(19) United States
(12) Patent Application Publication
(10) Pub. No.: US 2007/0137576 A1
(43) Pub. Date: Jun. 21, 2007

(54) Technique for providing an inductively coupled radio frequency plasma flood gun

(75) Inventors: Peter F. Kurunczi, Beverly, MA (US); Russell Low, Rowley, MA (US); Alexander S. Perel, Danvers, MA (US); Eric R. Cobb, Danvers, MA (US); Ethan Adam Wright, Ipswich, MA (US)

Correspondence Address: VARIAN SEMICONDUCTOR EQUIPMENT ASSC., INC., 35 DORY RD., GLOUCESTER, MA, 01930-2297, US

(73) Assignee: Varian Semiconductor Equipment Associates, Inc., Gloucester, MA (US)

(21) Appl. No.: 11/376,850

(22) Filed: Mar. 16, 2006

Related U.S. Application Data
(60) Provisional application No. 60/751,218, filed on Dec. 19, 2005.

(51) Int. Cl. H01J 7/24; C23C 16/00

(52) U.S. Cl. 118/723 R; 315/111.81

(57) ABSTRACT

A technique for providing an inductively coupled radio frequency plasma flood gun is disclosed. In one particular exemplary embodiment, the technique may be realized as a plasma flood gun in an ion implantation system. The plasma flood gun may comprise: a plasma chamber having one or more apertures; a gas source capable of supplying at least one gaseous substance to the plasma chamber; and a power source capable of inductively coupling radio frequency electrical power into the plasma chamber to excite the at least one gaseous substance to generate a plasma. Entire inner surface of the plasma chamber may be free of metal-containing material and the plasma may not be exposed to any metal-containing component within the plasma chamber. In addition, the one or more apertures may be wide enough for at least one portion of charged particles from the plasma to flow through.

### CROSS-REFERENCE TO RELATED APPLICATIONS

This patent application claims priority to U.S. Provisional Patent Application No. 60/751,218, filed Dec. 19, 2005, which is hereby incorporated by reference herein in its entirety.

### FIELD OF THE DISCLOSURE

The present disclosure relates generally to ion implantation and, more particularly, to a technique for providing an inductively coupled radio frequency plasma flood gun.

### BACKGROUND OF THE DISCLOSURE

During an ion implantation process, a semiconductor wafer is typically bombarded with positively charged ions. Unhindered, these positively charged ions may build up a positive charge on insulated portions of the wafer surface and lead to positive potentials thereon. The energetic ions can also contribute to further wafer charging through secondary electron emission from the wafer. The resulting positive potentials can create strong electric fields in some miniature structures and may cause permanent damage. A plasma flood gun (PFG) is commonly used to alleviate this charge buildup problem.

In an ion implantation system, a PFG is typically located close to an ion beam just before it makes its impact on a wafer. The PFG often comprises a plasma chamber wherein a plasma is generated through ionization of atoms of an inert gas such as argon (Ar), xenon (Xe) or krypton (Kr). Low-energy electrons from the plasma are introduced into the ion beam and drawn towards the positively charged wafer to neutralize the excessively positively charged wafer.

Existing PFG's suffer from a number of problems. A significant problem is metal contamination. One type of conventional PFG uses a hot tungsten filament for plasma generation. The tungsten filament is gradually consumed and tungsten atoms may contaminate the ion implantation system as well as wafers processed therein. Another common source of metal contaminants is the PFG plasma chamber. The inner surface of the plasma chamber often contains one or more metals or metal compounds. Constant exposure of the inner surface to plasma discharges may free metal atoms into the ion implantation system. Metal electrodes or other metal components placed inside the plasma chamber may cause similar contaminations. For example, some existing PFG's rely on metal electrodes to capacitively couple electrical power into their plasma chambers, wherein the metal electrodes have direct contact with the plasma. While some PFG's only indirectly couple microwave or radio frequency (RF) power into their plasma chambers, they often bias the plasma with internally placed electrodes. The plasma tends to corrode the metal electrodes or similar metal surfaces and lead to metal contamination. Although the contamination problem might be alleviated by constructing a plasma chamber completely out of a dielectric material, such a solution may not be desirable because the nonconductive inner surface increases plasma potential and therefore the energy of the emitted electrons. For charge neutralization in an ion implantation system, a relatively low electron energy is generally preferred.

Another challenge in designing a new PFG is to make it compact enough to fit into a predefined space reserved for a previous PFG. Existing PFG's are often so bulky or complex that their installation would require substantial modifications to existing ion implantation systems. However, it is often economically unfeasible to modify a mature ion implantation system just to accommodate a new PFG. Customers who are looking to upgrade a PFG for an otherwise perfect ion implanter prefer a compact yet effective PFG design that can easily fit.

In view of the foregoing, it would be desirable to provide a PFG which overcomes the above-described inadequacies and shortcomings.

### SUMMARY OF THE DISCLOSURE

A technique for providing an inductively coupled radio frequency plasma flood gun is disclosed. In one particular exemplary embodiment, the technique may be realized as a plasma flood gun in an ion implantation system. The plasma flood gun may comprise a plasma chamber having one or more apertures. The plasma flood gun may also comprise a gas source capable of supplying at least one gaseous substance to the plasma chamber. The plasma flood gun may further comprise a power source capable of inductively coupling radio frequency electrical power into the plasma chamber to excite the at least one gaseous substance to generate a plasma. Entire inner surface of the plasma chamber may be free of metal-containing material and the plasma may not be exposed to any metal-containing component within the plasma chamber. In addition, the one or more apertures may be wide enough for at least one portion of charged particles from the plasma to flow through.

In accordance with other aspects of this particular exemplary embodiment, a portion of the inner surface of the plasma chamber may comprise one or more materials selected from a group consisting of graphite and silicon carbide.

In accordance with further aspects of this particular exemplary embodiment, the power source may be coupled to the plasma chamber via a dielectric interface. The dielectric interface may comprise quartz.

In accordance with additional aspects of this particular exemplary embodiment, a bulk of the plasma may be magnetically confined in one or more magnetic cusps that are produced by a plurality of magnets placed outside the plasma chamber. The plurality of magnets may be further arranged to produce one or more magnetic dipoles to filter out high-energy electrons from the plasma.

In accordance with a further aspect of this particular exemplary embodiment, each of the one or more apertures may be wider than twice a sheath width of the plasma.

In accordance with a yet further aspect of this particular exemplary embodiment, an unbiased cage having an opening for an ion beam to pass through, wherein the plasma chamber may be positioned sufficiently close to the opening to allow the ion beam to transport the at least one portion of charged particles from the plasma. The one or more apertures may form an array that extends across a width of the ion beam or a scan width of the ion beam. Further, the ion beam may be directed at a wafer, and the one or more apertures may be tilted towards the wafer such that the exiting plasma joins the ion beam at an angle.

In accordance with a still further aspect of this particular exemplary embodiment, the one or more apertures may comprise a slit aperture.

In accordance with another aspect of this particular exemplary embodiment, the power source may comprise an elongated planar coil that extends alongside an external wall of the plasma chamber. The elongated planar coil may be made essentially of aluminum. The elongated planar coil may have: two or more turns spaced 1/16 to 1 inch apart, a bend radius in a range of ¼ to 1 inch, and a bend radius to bend radius length in a range of 6 to 16 inches. Preferably, The elongated planar coil may have: two turns spaced ⅛ inch apart; a bend radius of ½ inch; and a bend radius to bend radius length of 12.25 inches.

In accordance with yet another aspect of this particular exemplary embodiment, there may be no electrode located inside the plasma chamber. The at least one gaseous substance may comprise one or more substances selected from a group consisting of argon, krypton, xenon, and helium.

In accordance with still another aspect of this particular exemplary embodiment, the plasma chamber may comprise an aperture plate having: a length in a range of 6 to 16 inches, a width in a range of 2 to 4 inches, a height in a range of 1/16 to ¼ inches, and a plurality of apertures along the length, each aperture having a diameter in a range of 0.020 to 0.100 inches and a depth in a range of 0.005 to 0.050 inches. Preferably, the aperture plate may have: a length of 14 inches; a width of ½ inch, a height of ¼ inch, and ten apertures evenly spaced by 1.2 inches along the length and centered, each aperture having a diameter of 1.4 mm and a depth of 0.7 mm.

In another particular exemplary embodiment, the technique may be realized as a plasma flood gun in an ion implantation system. The plasma flood gun may comprise a plasma chamber having one or more apertures. The plasma flood gun may also comprise a gas source capable of supplying at least one gaseous substance to the plasma chamber. The plasma flood gun may further comprise a power source capable of inductively coupling radio frequency electrical power into the plasma chamber to excite the at least one gaseous substance to generate a plasma. Entire inner surface of the plasma chamber may comprise no metal other than aluminum, and the one or more apertures may be wide enough for at least one portion of charged particles from the plasma to flow through. The plasma chamber may comprise a dielectric interface to the power source and wherein the dielectric interface comprises aluminum oxide.

In yet another particular exemplary embodiment, the technique may be realized as a method for providing a plasma flood gun in an ion implantation system. The method may comprise providing a plasma chamber having a dielectric interface and one or more apertures, the entire inner surface of the plasma chamber being free of metal or metal compound. The method may also comprise supplying at least one gaseous substance to the plasma chamber. The method may further comprise generating a plasma by inductively coupling radio frequency electrical power into the plasma chamber to excite the at least one gaseous substance. The method may additionally comprise causing at least a portion of charged particles from the plasma to exit the plasma chamber via the one or more apertures.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 shows a side view of an exemplary PFG in accordance with an embodiment of the present disclosure.

FIG. 2 shows an exit aperture in a PFG in accordance with an embodiment of the present disclosure.

FIG. 3 shows a perspective view of an exemplary PFG in accordance with an embodiment of the present disclosure.

FIG. 4 shows a bottom view of a PFG with one exemplary arrangement of magnets in accordance with an embodiment of the present disclosure.

FIG. 5 shows a bottom view of a PFG with another exemplary arrangement of magnets in accordance with an embodiment of the present disclosure.

FIG. 6 shows a bottom view of a PFG with yet another exemplary arrangement of magnets in accordance with an embodiment of the present disclosure.

FIG. 7 shows a flow chart illustrating an exemplary method for providing a PFG in accordance with an embodiment of the present disclosure.

FIG. 8 shows an exemplary RF coil for use in a PFG in accordance with an embodiment of the present disclosure.

FIG. 9 shows an exemplary aperture plate for use in a PFG in accordance with an embodiment of the present disclosure.

FIG. 10 shows a bottom view of a PFG with still another exemplary arrangement of magnets in accordance with an embodiment of the present disclosure.

### DETAILED DESCRIPTION OF EXEMPLARY EMBODIMENTS

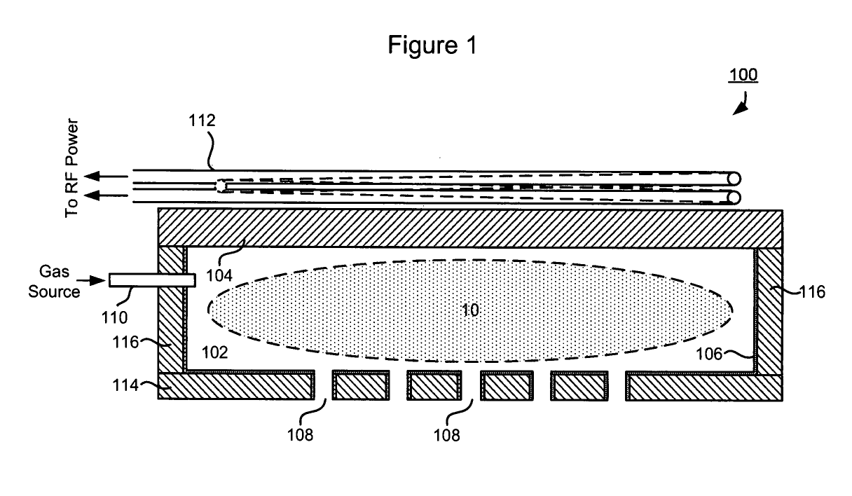

Referring to FIG. 1, there is shown a side view of an exemplary PFG 100 in accordance with an embodiment of the present disclosure.

The PFG 100 may comprise a plasma chamber 102 that has a substantially metal-free inner surface. In a preferred embodiment, no metal electrode or metal component may be placed inside the plasma chamber 102. Nor is there any exposed metal or metal compound in the plasma chamber 102. One side of the plasma chamber 102 may be a dielectric interface 104 that separates the inside of the plasma chamber 102 from a coil 112. The dielectric interface 104 may be made of quartz and/or other dielectric materials that contains no metal or metal compound. The other portions (e.g., an aperture plate 114 or sidewall 116) of the plasma chamber 102 may be made out of a non-metallic conductive material such as graphite or silicon carbide (SiC). Alternatively, the other portions of the inner surface may have a coating 106 of a non-metallic conductive material (e.g., graphite or SiC). The coating 106 may be applied over either a metal or non-metal surface. The coil 112 and/or the sidewall 116 may be cooled (to a desired temperature) with water or other coolants. For example, the coil 112 and the sidewall 116 may be hollow to allow circulation of a coolant therein.

According to some embodiments, a plasma chamber 102 with exposed aluminum (Al) or aluminum-containing materials (e.g., aluminum oxide or Al₂O₃) may be tolerated. In that case, the dielectric interface 104 may comprise aluminum oxide, and the other portions of the plasma chamber 102 may be made of or be coated with aluminum. Alternatively, one portion of the inner surface may be coated with a non-metallic conductive material while another portion may comprise exposed aluminum.

There may be a feed-through gas pipe 110 in a sidewall of the plasma chamber 102. Through the gas pipe 110, one or more gaseous substances may be supplied to the plasma chamber 102. The gaseous substances may include inert gases such as xenon (Xe), argon (Ar) or helium (He). The gas pressure is typically maintained in a range of 1-50 mTorr.

The coil 112 may have an elongated, planar shape that extends along one side of the PFG 100. The coil 112 may be connected to an RF power supply (not shown) and may inductively couple RF electrical power, through the dielectric interface 104, into the plasma chamber 102. The RF electrical power may operate at typical frequencies allocated to industrial, scientific and medical (ISM) equipment, such as, for example, 2 MHz, 13.56 MHz and 27.12 MHz.

The RF electrical power coupled into the plasma chamber 102 may excite the inert gases therein to generate a plasma 10. The shape and position of the plasma 10 inside the plasma chamber 102 may be affected at least in part by the shape and position of the coil 112. According to some embodiments, the coil 112 may extend substantially the whole length and width of the plasma chamber 102. Due to the metal-free inner surface, the plasma chamber 102 may be constantly exposed to the plasma 10 without introducing any metal contaminant. Further, the non-metallic conductive coating 106 may help lower the potential of the plasma 10 and therefore keep electrons from the plasma 10 at a low energy.

In an ion implantation system, the PFG 100 is typically located near an ion beam (not shown) just before it reaches a wafer (not shown). In a sidewall of the plasma chamber 102, there may be a plurality of exit apertures 108 leading into the ion implantation system. The exit apertures 108 may form an array that extent across a width of the ion beam. For example, for a ribbon-shaped ion beam, the exit apertures 108 may cover substantially the ribbon width. In the case of a scanned ion beam, the exit apertures 108 may cover the scan width. According to one embodiment of the present disclosure, the exit apertures 108 may cover a width of 11-12 inches.

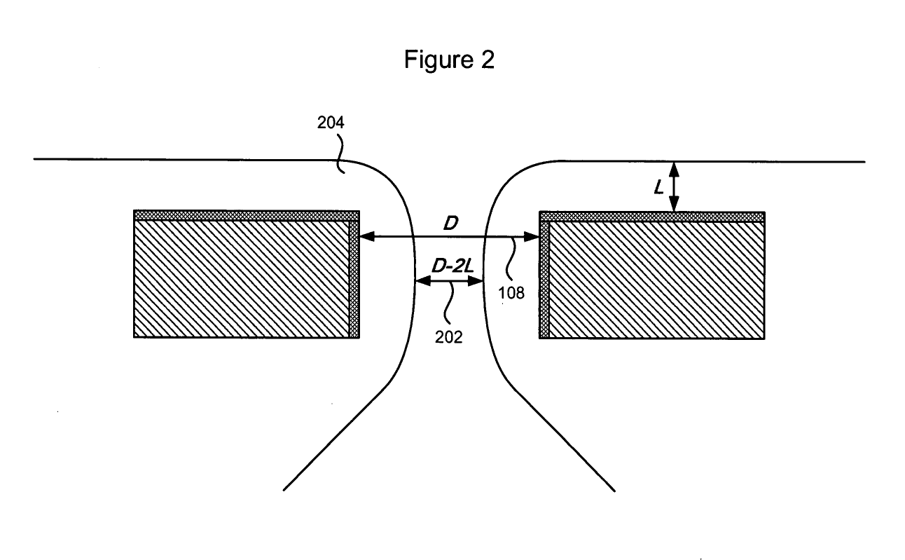

To allow charged particles (i.e., electrons and ions) from the plasma 10 to pass through the exit apertures 108, the width of the exit apertures 108 is typically greater than twice of the sheath width of the plasma 10. FIG. 2 shows an exit aperture 108 in accordance with an embodiment of the present disclosure. The actual width of the aperture 108 may be denoted as D. The plasma sheath 204 (i.e., a boundary layer between the plasma 10 and the sidewall) may have a width of L. Then, an effective aperture 202 has a width of (D-2 L). According to one embodiment, it may be desirable for the plasma 10 to form a plasma bridge with an ion beam passing just outside the plasma chamber 102. Therefore, it may be desirable that D be greater than 2 L so that the effective aperture 202 is wide enough to accommodate the plasma bridge.

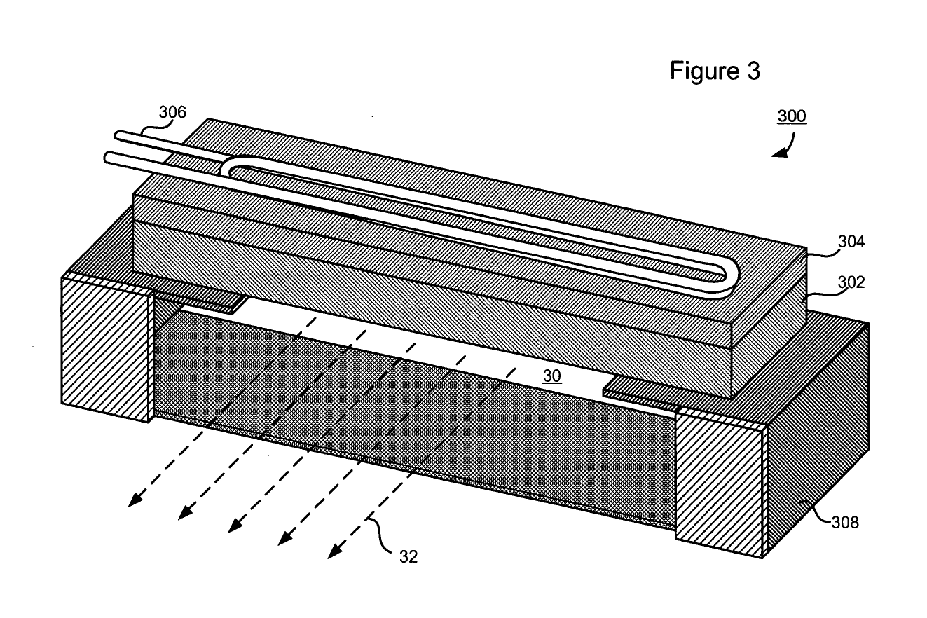

FIG. 3 shows a perspective view of an exemplary PFG 300 in accordance with an embodiment of the present disclosure. The PFG 300 may comprise a plasma chamber 302 having a dielectric interface 304 on its top side. Via the dielectric interface 304, a coil 306 may inductively couple RF electrical power into the plasma chamber 302 to generate a plasma out of one or more inert gases. Charged particles, especially electrons, that are generated from the plasma may flow through exit apertures (not shown) or at least one slit on the bottom side of the plasma chamber 302. The plasma chamber 302 may be mounted on a cage 308. The cage 308 may be preferably unbiased and may have an opening 30 through which an ion beam 32 passes. The plasma inside the plasma chamber 302 may form plasma bridges with the ion beam 32, whereby the ion beam 32 may carry low-energy electrons generated from the plasma towards a positively charged wafer.

According to embodiments of the present disclosure, the simple design of the PFG 300 makes it adaptable to fit within a predefined space reserved for an older type PFG. Therefore, there may be no need to alter an existing PFG housing for the upgrade.

Although FIG. 3 shows the PFG 300 with its exit apertures facing downwards at the ion beam 32, that is not the only orientation contemplated. Either the bulk of the PFG 300 or the exit apertures may be tilted so that the plasma bridges join the ion beam 32 at an angle. For example, the PFG 300 may be adapted so that electrons (or the plasma bridges) coming out of the exit apertures are directed in a general direction of a wafer and join the ion beam 32 at a 45 degree angle. Other angles are also contemplated.

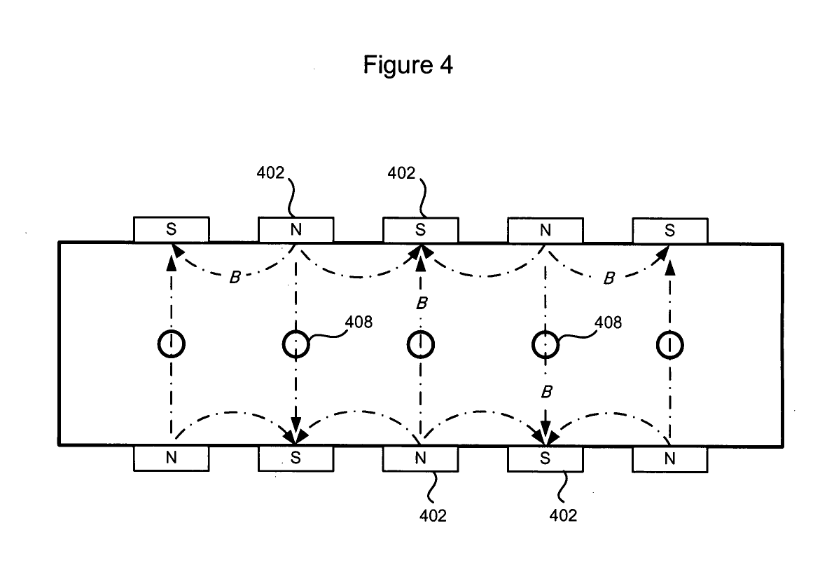

According to other embodiments of the present disclosure, flexible configurations of magnets may be provided outside a PFG plasma chamber to achieve an effective plasma confinement in the plasma chamber. Two exemplary configurations are shown in FIGS. 4-6 and 10.

FIG. 4 shows a bottom view of a PFG with one exemplary arrangement of magnets in accordance with an embodiment of the present disclosure. The PFG may be the same as or similar to the PFG 300 shown in FIG. 3. There may be a plurality of exit apertures 408 in the bottom of the PFG plasma chamber. Multiple magnets 402 (e.g., permanent magnets or electromagnet coils) may be placed on both sides of the plasma chamber, alternating north poles with south poles and with different poles opposite each other. This arrangement may create cusps as well as dipoles in the magnetic field, wherein the magnetic cusps serve to confine the plasma lengthwise within the plasma chamber and the magnetic dipoles serve to filter out high-energy electrons.

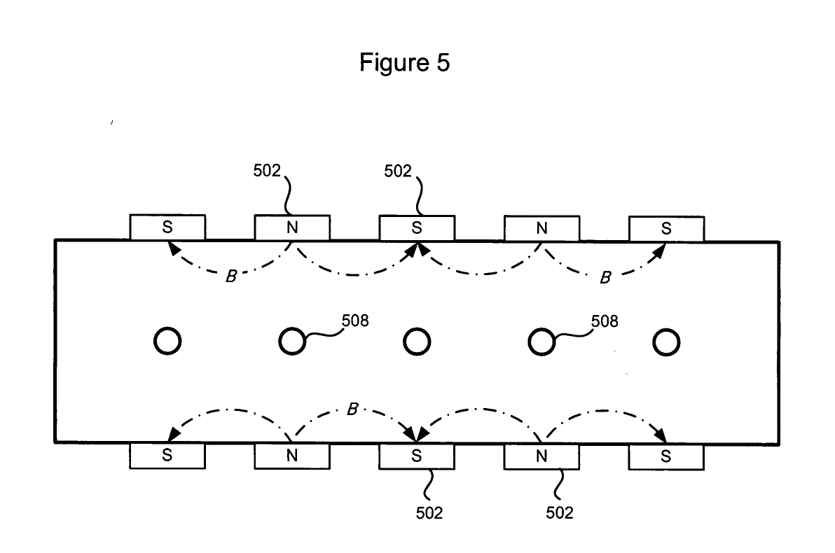

FIG. 5 shows a bottom view of a PFG with another exemplary arrangement of magnets in accordance with an embodiment of the present disclosure. There may be a plurality of exit apertures 508 in the bottom of the PFG plasma chamber. The arrangement of magnets here is slightly different from what is shown in FIG. 4. Multiple magnets 502 may be placed on both sides of the plasma chamber, alternating north poles with south poles but with same poles opposite each other. This arrangement only creates cusps but no dipoles in the magnetic field.

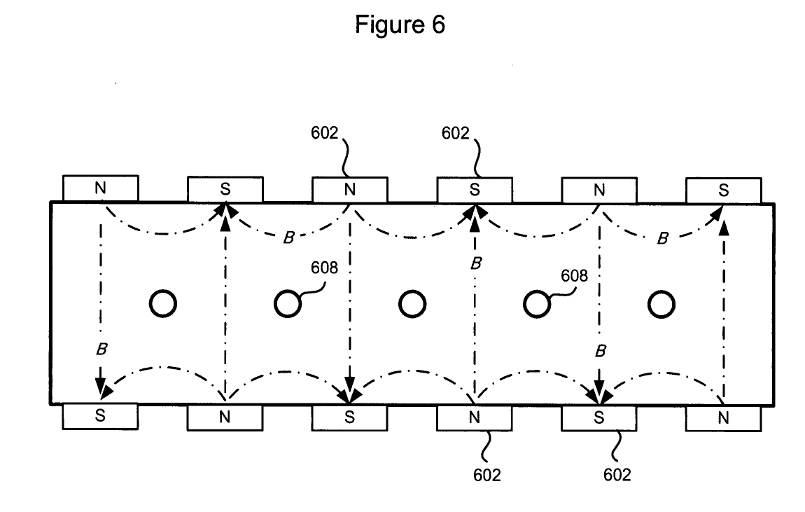

FIG. 6 shows a bottom view of a PFG with yet another exemplary arrangement of magnets in accordance with an embodiment of the present disclosure. Unlike what is shown in FIG. 4, magnets 602 may be so positioned that those opposite each other are not aligned with apertures 608.

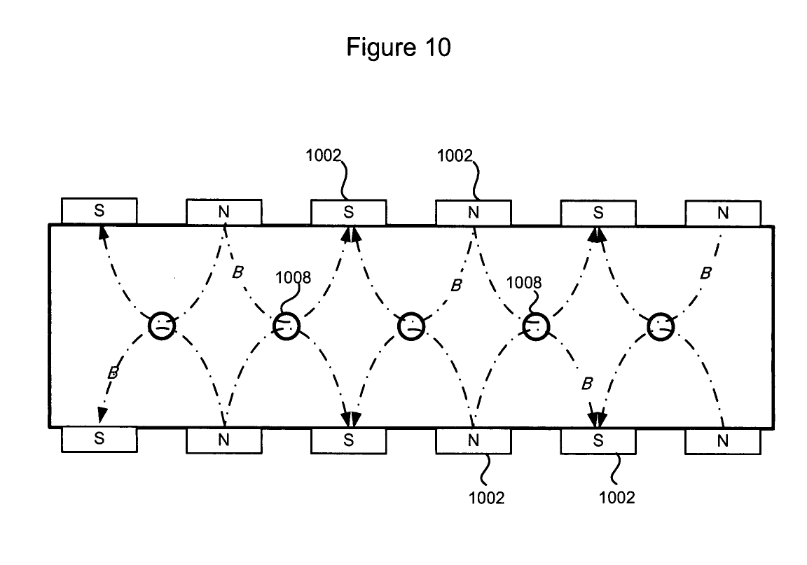

FIG. 10 shows a bottom view of a PFG with still another exemplary arrangement of magnets in accordance with an embodiment of the present disclosure. In this arrangement, magnets 1002 are placed along the length of the PFG, wherein those opposite each other are not aligned with apertures 1008. Thus, multi-pole fields B confine plasma along the length of the PFG, increasing plasma density and lowering the plasma potential. In addition, the multi-pole field lines also extend across the apertures 1008.

As illustrated in FIGS. 4-6 and 10, the magnets may be flexibly arranged and re-arranged to create a desired magnetic field inside a PFG plasma chamber to confine a plasma therein. By changing the strength and shape of the magnetic field, the uniformity and density of the plasma may be adjusted. As a result, electron diffusion losses to the sidewalls of the plasma chamber may be reduced. The proper plasma confinement may also reduce plasma potential and sheath width thereby enhancing electron output.

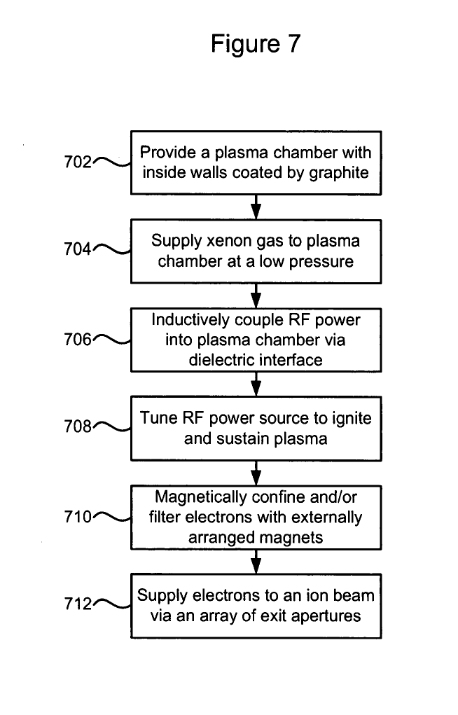

FIG. 7 shows a flow chart illustrating an exemplary method for providing a PFG in accordance with an embodiment of the present disclosure.

In step 702, a plasma chamber may be provided. Inside walls of the plasma chamber may be coated with graphite or other non-metallic conductive materials to prevent contamination.

In step 704, a xenon (Xe) gas may be supplied to the plasma chamber at a low pressure of 10-20 mTorr. Xenon may be a preferred gas for PFG purposes due to a relatively low ionization potential among inert gases and its heavy mass.

In step 706, RF power may be inductively coupled into the plasma chamber via a dielectric interface. Inductive coupling eliminates the need of placing electrodes or other metal components inside the plasma chamber.

In step 708, the RF power may be tuned to ignite and sustain a xenon plasma. To break down the xenon gas atoms, it may be desirable to start with a relatively high gas pressure and/or a high RF power setting. Once the plasma has been ignited, it may be sustained at a lower gas pressure and/or RF power setting.

In step 710, the plasma may be magnetically confined and electrons from the plasma may be magnetically filtered with externally placed permanent magnets. The permanent magnets may be arranged in a multi-pole configuration to improve plasma density and uniformity and therefore enhance electron generation.

In step 712, the electrons generated from the plasma may be supplied, via an array of exit apertures in the plasma chamber, to an ion beam just before it hits a wafer. The ion beam may serve as a carrier for the drifting, low-energy electrons. As soon as the wafer becomes slightly charged to a positive potential, the electrons may be drawn towards the wafer to neutralize the excess of positive charges.

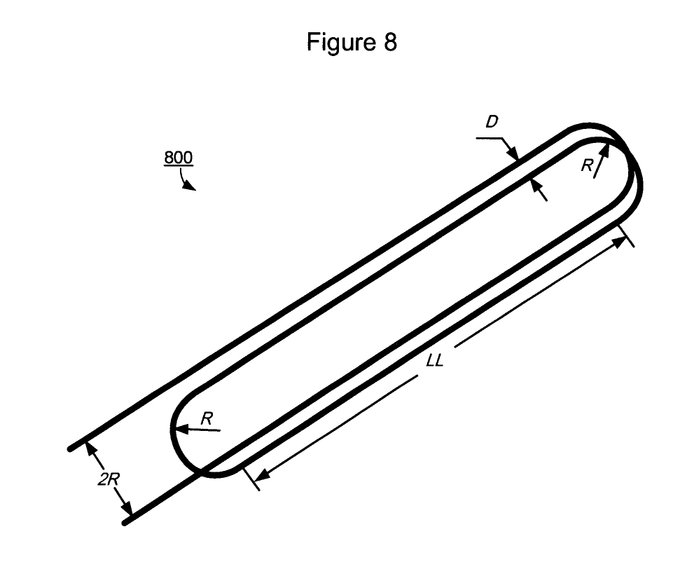

FIG. 8 shows an exemplary RF coil 800 for use in a PFG in accordance with an embodiment of the present disclosure. The RF coil 800 may replace, for example, the coil 112 shown in FIG. 1 and the coil 306 shown in FIG. 3. The coil 800 may have an elongated shape with two or more turns. Two adjacent turns may have a spacing D of 1/16-½ inch between them. The bend radius R may be in the range of ¼-¾ inch. The bend radius to bend radius length LL may be in the range of 8-20 inches. According to one preferred embodiment, the RF coil 800 may have two turns spaced ⅛ inch apart with one on top of the other. The bend radius R may be ½ inch, thus there is a one inch (2R) space between the two long arms of the RF coil 800. The bend radius to bend radius length LL may be 12 inches.

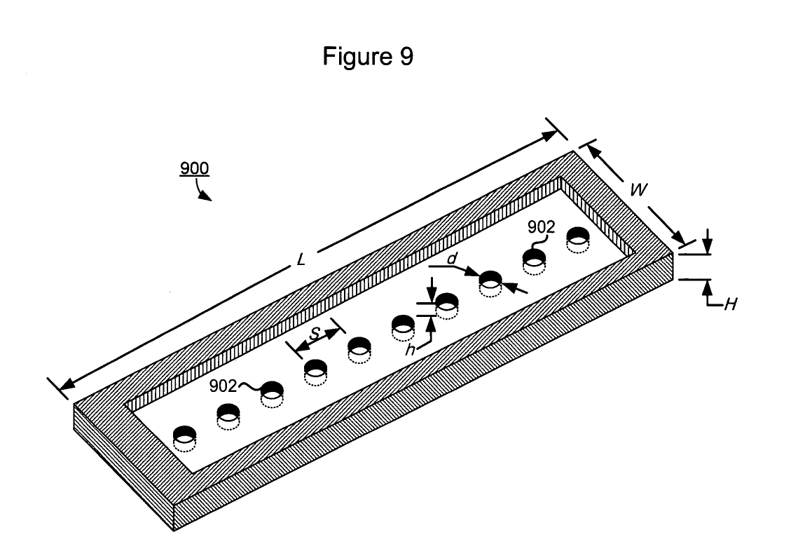

FIG. 9 shows an exemplary aperture plate 900 for use in a PFG in accordance with an embodiment of the present disclosure. The aperture plate 900 may be made of, for example, graphite, aluminum, silicon carbide, or metal with a graphite or silicon carbide coating. The aperture plate 900 may have a length L in the range of 6 to 16 inches, a width W in the range of 2 to 4 inches, and a height H in the range of 1/16 to 0.25 inches. On the inside (plasma chamber side) of the aperture plate 900, there may be a recessed region having a plurality of exit apertures 902. The exit apertures 902, with a diameter d in the range of 0.020 to 0.100 inches, may be evenly spaced along a center line of the aperture plate 900. The spacing S between the center of two adjacent exit apertures 902 may be in the range of 0.1 to 3 inches. The depth h of each exit aperture 902 may be in the range of 0.005 to 0.050 inches. According to one preferred embodiment, the aperture plate 900 may have a length L of 14 inches, a width W of ½ inch, and a height H of ¼ inch. There may be 10 exit apertures 902 spaced 1.2 inches along the length and centered. Each exit aperture 902 may have a diameter d of 1.4 mm and a depth h of 0.7 mm.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A plasma flood gun in an ion implantation system, the plasma flood gun comprising:
a plasma chamber having one or more apertures;
a gas source capable of supplying at least one gaseous substance to the plasma chamber; and
a power source capable of inductively coupling radio frequency electrical power into the plasma chamber to excite the at least one gaseous substance to generate a plasma;
wherein entire inner surface of the plasma chamber is free of metal-containing material and the plasma is not exposed to any metal-containing component within the plasma chamber, and wherein the one or more apertures are wide enough for at least one portion of charged particles from the plasma to flow through.

2. The plasma flood gun according to claim 1, wherein a portion of the inner surface of the plasma chamber comprises one or more materials selected from a group consisting of graphite and silicon carbide.

3. The plasma flood gun according to claim 1, wherein the power source is coupled to the plasma chamber via a dielectric interface.

4. The plasma flood gun according to claim 3, wherein the dielectric interface comprises quartz.

5. The plasma flood gun according to claim 1, wherein a bulk of the plasma is magnetically confined in one or more magnetic cusps that are produced by a plurality of magnets placed outside the plasma chamber.

6. The plasma flood gun according to claim 5, wherein the plurality of magnets are further arranged to produce one or more magnetic dipoles to filter out high-energy electrons from the plasma.

7. The plasma flood gun according to claim 1, wherein each of the one or more apertures is wider than twice a sheath width of the plasma.

8. The plasma flood gun according to claim 1, further comprising:
an unbiased cage having an opening for an ion beam to pass through, wherein the plasma chamber is positioned sufficiently close to the opening to allow the ion beam to transport the at least one portion of charged particles from the plasma.

9. The plasma flood gun according to claim 8, wherein the one or more apertures form an array that extends across a width of the ion beam or a scan width of the ion beam.

10. The plasma flood gun according to claim 8, wherein:
the ion beam is directed at a wafer; and
the one or more apertures are tilted towards the wafer such that the exiting plasma joins the ion beam at an angle.

11. The plasma flood gun according to claim 1, wherein the one or more apertures comprise a slit aperture.

12. The plasma flood gun according to claim 1, wherein:
the power source comprises an elongated planar coil that extends alongside an external wall of the plasma chamber.

13. The plasma flood gun according to claim 12, wherein the elongated planar coil is made essentially of aluminum.

14. The plasma flood gun according to claim 12, wherein the elongated planar coil has:
two or more turns spaced 1/16 to 1 inch apart;
a bend radius in a range of ¼ to 1 inch; and
a bend radius to bend radius length in a range of 6 to 16 inches.

15. The plasma flood gun according to claim 14, wherein the elongated planar coil has:
two turns spaced ⅛ inch apart;
a bend radius of ½ inch; and
a bend radius to bend radius length of 12.25 inches.

16. The plasma flood gun according to claim 1, wherein there is no electrode located inside the plasma chamber.

17. The plasma flood gun according to claim 1, wherein the at least one gaseous substance comprises one or more substances selected from a group consisting of argon, krypton, xenon, and helium.

18. The plasma flood gun according to claim 1, wherein the plasma chamber comprises an aperture plate having:
a length in a range of 6 to 16 inches;
a width in a range of 2 to 4 inches;
a height in a range of 1/16 to ¼ inches; and
a plurality of apertures along the length, each aperture having a diameter in a range of 0.020 to 0.100 inches and a depth in a range of 0.005 to 0.050 inches.

19. The plasma flood gun according to claim 18, wherein the plasma chamber comprises an aperture plate having:
a length of 14 inches;
a width of ½ inch;
a height of ¼ inch; and
ten apertures evenly spaced by 1.2 inches along the length and centered, each aperture having a diameter of 1.4 mm and a depth of 0.7 mm.

20. A plasma flood gun in an ion implantation system, the plasma flood gun comprising:
a plasma chamber having one or more apertures;
a gas source capable of supplying at least one gaseous substance to the plasma chamber; and
a power source capable of inductively coupling radio frequency electrical power into the plasma chamber to excite the at least one gaseous substance to generate a plasma;
wherein entire inner surface of the plasma chamber comprises no metal other than aluminum, and wherein the one or more apertures are wide enough for at least one portion of charged particles from the plasma to flow through.

21. The plasma flood gun according to claim 20, wherein the plasma chamber comprises a dielectric interface to the power source and wherein the dielectric interface comprises aluminum oxide.

22. A method for providing a plasma flood gun in an ion implantation system, the method comprising:
providing a plasma chamber having a dielectric interface and one or more apertures, the entire inner surface of the plasma chamber being free of metal or metal compound;
supplying at least one gaseous substance to the plasma chamber;
generating a plasma by inductively coupling radio frequency electrical power into the plasma chamber to excite the at least one gaseous substance; and
causing at least a portion of charged particles from the plasma to exit the plasma chamber via the one or more apertures.
